(19) United States
(12) Patent Application Publication
(10) Pub. No.: US 2010/0187096 A1
(43) Pub. Date: Jul. 29, 2010

(54) MANUFACTURING METHOD OF AN ELECTRON-EMITTING DEVICE, AND MANUFACTURING METHOD OF A LANTHANUM BORIDE FILM

(75) Inventors: Naofumi Aoki, Chigasaki-shi (JP); Tamaki Kobayashi, Isehara-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/691,437

(22) Filed: Jan. 21, 2010

(30) Foreign Application Priority Data
Jan. 29, 2009 (JP) 2009-018202

(51) Int. Cl. C23C 14/34

(52) U.S. Cl. 204/192.15

(57) ABSTRACT

A lanthanum boride film is deposited on a substrate by means of a sputtering method while moving the substrate and a target of lanthanum boride relative to each other in a state where the substrate and the target are arranged in opposition to each other. When a mean free path of sputtering gas molecules at the time of deposition is λ (mm) and a distance between the substrate and the target is L (mm), a ratio of L/λ is set to a value equal to or larger than 20. A value which is obtained by dividing a discharge power value by an area of the target is set to be in a range of from 1 W/cm² or more to 5 W/cm² or less.

### BACKGROUND OF THE INVENTION

1. Field of the Invention

The present invention relates to a manufacturing method of a lanthanum boride film using a sputtering method, and a manufacturing method of an electron-emitting device having a lanthanum boride film.

2. Description of the Related Art

A field emission type electron-emitting device is an electron-emitting device of the type that applies a voltage (electric field) across a cathode electrode (and an electron emission structure arranged thereon) and a gate electrode, and pulls out electrons into a vacuum from a cathode electrode side by means of this voltage (electric field). Therefore, the operating electric field is greatly influenced by the work function, shape, etc., of the cathode electrode (electron emission structure) to be used. Theoretically, it is considered that the smaller the work function of the cathode electrode (electron emission film), with the lower operating voltage the cathode electrode can be driven. In Japanese patent application laid-open No. H01-235124 and U.S. Pat. No. 4,008,412, there is disclosed an electron-emitting device that has a lanthanum hexaboride (LaB₆) film as an electron-emitting member of a low work function coated on an electron emission structure (Spindt, etc.) made of metal. In addition, in Japanese patent application laid-open No. 2000-173365 and Japanese patent application laid-open No. 2001-270795, there are disclosed a sputtering method and a sputtering system.

### SUMMARY OF THE INVENTION

In producing an electron-emitting device using a lanthanum boride film, it is preferable, from the viewpoint of the stability of electron emission, etc., that the film has higher crystallinity. In addition, in the orientation of crystals, an orientation to a (100) surface among other orientations serves to stabilize electron emission. This is because the (100) surface has less surface dangling bonds as compared with a (110) surface or a (111) surface, and has lower impurity adsorption capacity.

However, according to a study of the present inventors, it was proved that in the deposition of a film by means of a sputtering method, the crystallinity and orientation of a lanthanum boride film are greatly changed by a difference in the film deposition condition.

FIG. 5A is a layout view of a parallel plate type sputtering apparatus that has been well known in the past. 501 denotes a substrate holder, 502 a substrate, and 503 a cathode. The cathode 503 is composed of a target 505, a backing plate 506, a magnet 507, and a yoke 508. A magnetic field is generated by the magnet 507, as represented by magnetic lines of force 509, and 504 denotes an erosion region. With the use of such an apparatus, lanthanum boride was deposited to a thickness of 50 nm on a Si wafer substrate to form a film while using an 8-inch circular member of lanthanum hexaboride as a target and the Si wafer substrate as a substrate 502, by holding the temperature of the substrate at room temperature, and by supplying Ar so as to provide a total pressure of 1.5 Pa. RF electric power supplied to the target was 500 W, and the distance between the target and the substrate was 90 mm. By analyzing the lanthanum boride film deposited as a result thereof by means of an X-ray diffraction method, and by reorganizing the relation between the full width at half maximum (FWHM) of a diffraction peak on the (100) surface and the position of the substrate, the following result was obtained as shown in FIG. 5B. The smaller the FWHM, the larger the crystallite size of crystals becomes, thus showing good crystals. With respect to the position of the substrate, the distance thereof from the center of the target illustrated in FIG. 5A is shown. As shown in FIG. 5B, at a position in opposition to the erosion region, the FWHM is large, and on the other hand, as the substrate position moves away from the position in opposition to the erosion region, the FWHM becomes smaller. That is, it was found that the film quality varies and the crystallinity of the lanthanum boride film becomes low at the position in opposition to the erosion region. As a result of a further study, it turned out that even if the distribution of plasma density is changed by changing the magnetic field of the magnet, the crystallinity of that portion of the lanthanum boride film which is in opposition to the erosion region is always low. That is, it was found that the film quality has stronger correlation with the position of the erosion region rather than the plasma density distribution. Hereinafter, the region (or position) which is in opposition to the erosion region is called an erosion opposed region (or position). In addition, a region which is not the erosion region is called a non-erosion region, and a region (or position) which is in opposition to the non-erosion region is called a non-erosion opposed region (or position).

The cause for the fact that the crystallinity of a film decreases in an erosion opposed position when a lanthanum boride target is used is not clear, but according to the study of the present inventors, it was found that a position dependency of the film quality exists at least in sputtering using a lanthanum boride target. On the other hand, in cases where an electron-emitting device is used for an electron source of an image display device, it is desirable to deposit a lanthanum boride film on a substrate of a large size as homogeneously as possible. Accordingly, in order to ease the position dependency of the film quality, a so-called moving deposition is performed in which the deposition of a film is carried out while moving a substrate and a target relatively to each other. In the moving deposition, a film deposited part (electron-emitting device) on the substrate passes through both of the erosion opposed region and the non-erosion opposed region. At this time, when a variation between the film quality of the film deposited in the erosion opposed region and the film quality of the film deposited in the non-erosion opposed region was large, it was difficult to produce a lanthanum boride film of good crystallinity in which a (100) surface was oriented.

As a method for preventing the damage of a film in an erosion opposed region due to oxygen anions at the time of using an oxide target instead of a lanthanum boride target, there has been known the arrangement of a shield plate (Japanese patent application laid-open No. 2000-173365, and Japanese patent application laid-open No. 2001-270795). However, it is difficult to produce a lanthanum boride film of good crystallinity according to this method.

The result of a study of the present inventors about the arrangement of a shield plate will be described. According to the inventors, a shield plate was arranged in a space between a target and a substrate in a manner to hide an erosion opposed region, and the sputtering deposition of lanthanum boride was performed. As a result, the crystallinity of a lanthanum boride film thus produced decreased to a remarkable extent, as compared with the case where the sputtering is performed without the arrangement of the shield plate. This is due to the possibility that plasma might be disturbed by the arrangement of the shield plate, thus causing a shortage of deposition energy. Even when the sputtering gas pressure and/or the sputtering power were adjusted, the crystallinity of the film remained substantially decreased in comparison with the case where the sputtering was performed without the arrangement of the shield plate.

The present invention has been made in view of the above-mentioned actual circumstances, and has for its object to provide a technique which improves a variation in film quality in a sputtering method thereby to produce a lanthanum boride film of good crystallinity. Another object of the present invention is to provide a technique which forms a lanthanum boride film of homogeneous film quality (crystallinity) on a substrate of a large area. In addition, a further object of the present invention is to provide a manufacturing method of an electron-emitting device which is excellent in an electron emission characteristic (in particular, the stability of electron emission).

The present invention in its first aspect provides a manufacturing method of an electron-emitting device provided with a lanthanum boride film as an electron-emitting member, the method comprising the steps of: preparing a substrate and a target of lanthanum boride; and depositing a lanthanum boride film on the substrate by means of a sputtering method while moving the substrate and the target relative to each other in a state where the substrate and the target are arranged in opposition to each other, wherein when a mean free path of sputtering gas molecules at the time of deposition is λ (mm) and a distance between the substrate and the target is L (mm), a ratio of L/λ is set to a value equal to or larger than 20; and a value which is obtained by dividing a discharge power value by an area of the target is set to be in a range of from 1 W/cm² or more to 5 W/cm² or less.

The present invention in its second aspect provides a manufacturing method of a lanthanum boride film, comprising the steps of: preparing a substrate and a target of lanthanum boride; and depositing a lanthanum boride film on the substrate by means of a sputtering method in a state where the substrate and the target are arranged in opposition to each other, wherein when a mean free path of sputtering gas molecules at the time of deposition is λ (mm) and a distance between the substrate and the target is L (mm), a ratio of L/λ is set to a value equal to or larger than 20.

According to the present invention, it is possible to improve a variation in film quality in a sputtering method thereby to produce a lanthanum boride film of good crystallinity. In addition, it is possible to form a lanthanum boride film of homogeneous film quality (crystallinity) on a substrate of a large area. Moreover, it is possible to produce an electron-emitting device that is excellent in the electron emission characteristic (in particular the stability of electron emission).

Further features of the present invention will become apparent from the following description of exemplary embodiments with reference to the attached drawings.

### BRIEF DESCRIPTION OF THE DRAWINGS

FIG. 1 is a view showing the relation between the crystallinity of a lanthanum hexaboride film and a deposition condition (L/λ).

FIG. 2A through FIG. 2C are schematic diagrams showing an example of an electron-emitting device.

FIG. 3 is a cross-sectional schematic diagram of a polycrystalline film of lanthanum boride.

FIG. 4A through FIG. 4F are schematic diagrams showing an example of a manufacturing method of an electron-emitting device.

FIG. 5A is a schematic diagram of a parallel plate type sputtering apparatus, and FIG. 5B is a view showing the relation between the crystallinity of the lanthanum hexaboride film and the position of deposition thereof.

### DESCRIPTION OF THE EMBODIMENTS

Hereinafter, preferred embodiments of this invention will be described with reference to the accompanying drawings. However, the dimensions, materials, shapes, relative arrangements and so on of component parts described in the embodiments are not intended to limit the scope of the present invention to these alone in particular as long as there are no specific statements.

(Sputtering Method)

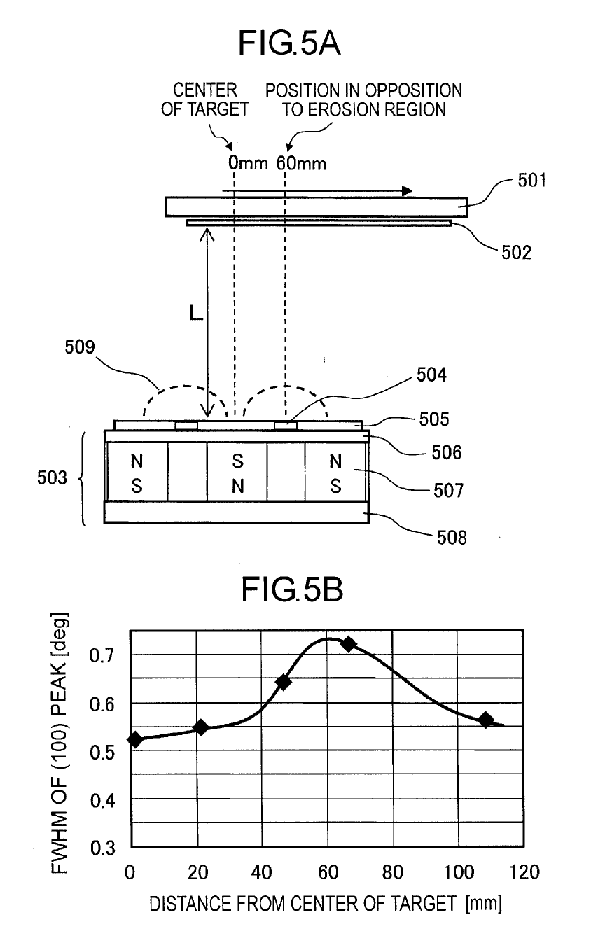

A sputtering apparatus and a sputtering method will be described with reference to FIG. 5A. FIG. 5A is a view schematically showing the interior of a chamber of a parallel-plate sputtering apparatus. The sputtering apparatus is roughly provided with a substrate holder 501 for holding a substrate 502, and a cathode 503 on which a target 505 is to be installed. The cathode 503 has a backing plate 506, a magnet 507, and a yoke 508. The magnet 507 is composed of an outer magnet of a doughnut shape, and an inner magnet that is arranged at the center of the outer magnet, wherein a magnetic field as indicated by the magnetic lines of force 509 is formed by means of this magnet 507. By this magnetic field, a single erosion region 504 of a doughnut shape is formed in the target 505.

After vacuum drawing the interior of the chamber to a vacuum pressure of 2×10⁻⁴ Pa or less by the use of a high vacuum exhaust pump, deposition or film formation is carried out by introducing a sputtering gas into the chamber, holding it at a predetermined pressure, and applying electric power to the cathode 503. Although an argon (Ar) gas, a krypton (Kr) gas, a xenon (Xe) gas, or the like can be used as the sputtering gas, it is in particular desirable to use an argon gas from the point of view of manufacturing costs. As a sputtering power source, a DC power supply or an RF power supply of an industrial power supply frequency such as 13.56 MHz is used.

In this sputtering apparatus, the target 505 and the substrate 502 are arranged in opposition to each other, and the substrate 502 and the target 505 are relatively moved with respect to each other by conveying or moving the substrate 502 in an arrow direction in FIG. 5A at the time of deposition (moving deposition). Here, note that the target 505 alone may be conveyed, or both the substrate 502 and the target 505 may be conveyed. In addition, not only a translational movement but also a rotational movement may be employed.

At this time, a distance L (mm) between the substrate 502 and the target 505 is held in such a manner that a value (L/λ), which is obtained by dividing the distance L by the mean free path λ (mm) of molecules of the sputtering gas introduced into the chamber, becomes 20 or more.

The mean free path λ of the gas is the average of distances which gas molecules can travel without scattering (collision), and it can be calculated by the following formula.

λ=(k×T)/(2^{1/2}×π×σ²×P)

where k is Boltzmann constant; T is temperature; σ is the diameter of a molecule; and P is pressure.

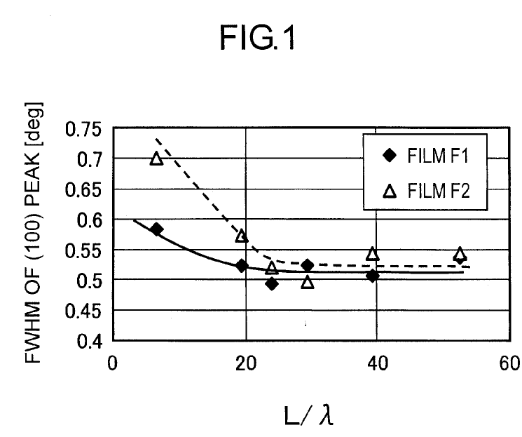

The results investigated for the ratio L/λ at the time of deposition and the crystallinity of a film are shown in FIG. 1. However, in order to compare the crystallinity of the film in the erosion opposed region thereof and that in the non-erosion opposed region thereof, the film was formed or deposited not by moving deposition but in a state where the substrate was held stationary. In addition, the deposition was carried out by setting the pressure of the argon gas to be introduced to an arbitrary value within the range of from 0.5 Pa to 4.0 Pa (that is, the mean free path λ of Ar molecules is in the range of from 1.7 to 13.7 mm), and by setting the distance L (mm) between the substrate and the target to an appropriate value within the range of from 90 to 180 mm. The value, which is obtained by dividing the discharge power of the RF power supply by the area of the target, was set to about 1.5 W/cm².

A film F1 deposited at a depth of 50 nm in the non-erosion opposed region (region in opposition to the center of the target) and a film F2 deposited at a depth of 50 nm in the erosion opposed region are analyzed by means of an X-ray diffraction method, and the FWHM of a diffraction peak on the (100) surface of lanthanum hexaboride (hereinafter also simply called “a (100) peak”) was obtained. FIG. 1 shows the relation between the deposition condition (L/λ) and the FWHM of the (100) peak. From FIG. 1, it is found out that the smaller the deposition condition (L/λ), the larger the FWHM of the (100) peak is, i.e., the worse the crystallinity of the film is. Also, the difference in crystallinity between the film F1 and the film F2 is larger. In addition, it is found that the larger the deposition condition (L/λ), the more the crystallinity is improved, and the smaller the difference in crystallinity between the film F1 and the film F2 also becomes.

As stated above, in cases where the lanthanum hexaboride film is used as an electron-emitting member for the electron-emitting device, it is preferable, from the point of view of the stability of electron emission, etc., that the film have good crystallinity. In addition, in order to make small the difference in the electron emission characteristic among individual electron-emitting devices (in-surface variation of the electron emission characteristic), it is preferable to deposit the lanthanum boride film over the entire substrate as homogeneously as possible.

However, if the crystallinity of either of the film formed in the erosion opposed region or the film formed in the non-erosion opposed region is bad, a film which is produced by means of moving deposition will include a component with a bad crystallinity. So, a good crystalline film will not be obtained. In addition, also in cases where there is a difference between the crystallinities of both the films, the electron emission characteristic of a film produced by means of moving deposition will become unstable.

Accordingly, in order to obtain a good electron emission characteristic, a condition is required which is able to make small the variation in the film quality of a deposition region, and is able to produce a film of good crystallinity over a large area. Specifically, the following condition is preferable; the in-surface variation of the FWHM of the (100) peak is within ±5%, and the FWHM of the (100) peak is equal to or less than 0.6 degrees. From an experimental result shown in FIG. 1, it can be seen that the above-mentioned condition can be satisfied in cases where the value of L/λ is 20 or more.

The reason why the film quality (crystallinity) can be improved by keeping the value of L/λ equal to or more than 20 is not clear. However, it can probably be considered to be one factor that by making the value of L/λ equal to or larger than 20, particles with large energy jumping vertically from the erosion region are able to be fully scattered about thereby to suppress the damage to the film at an erosion opposed position.

As described above, the pressure of the sputtering gas and the distance of the substrate and the target greatly affect the crystallinity of the lanthanum boride film. On the other hand, the influence which discharge power has on the crystallinity of the film is small. However, it is preferable to set a value, which is obtained by dividing the discharge power by the area of the target, to be within a range of from 1 W/cm² or more to 5 W/cm² or less. This is due to the following reasons. In cases where the value is less than 1 W/cm², the energy of atoms being sputtered is so small that it is difficult to produce a film of good crystallinity. In addition, in cases where the value exceeds 5 W/cm², the load to the target is large and there is a possibility that the target may be damaged. Here, note that if the value is in the range of from 1 W/cm² or more to 5 W/cm² or less, the relation between the value of L/λ and the film quality generally exhibits a trend as shown in FIG. 1.

In this embodiment, it is preferable to deposit a film on a substrate while heating the substrate or keeping it warm. Although an appropriate temperature for the substrate changes with the deposition condition or the like, it is preferable to keep the temperature of the substrate at a value equal to or higher than 300 degrees C.

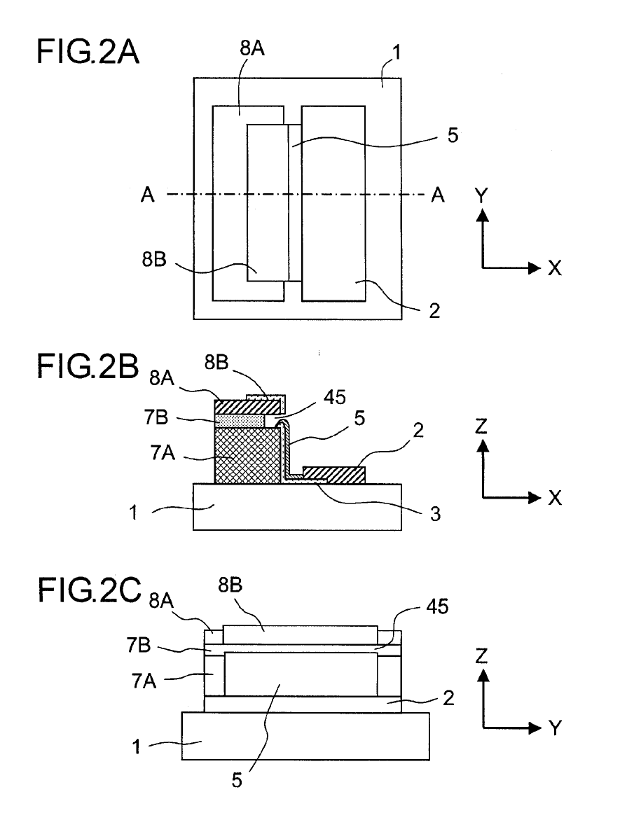

Next, reference will be made to a manufacturing method of a field emission type electron-emitting device provided with a lanthanum boride film produced according to this embodiment while using FIG. 2A, FIG. 2B and FIG. 2C. FIG. 2A is a plan schematic diagram looking at the electron-emitting device from a direction of Z, and FIG. 2B is a cross-sectional (Z-X surface) schematic diagram taken on line A-A in FIG. 2A. FIG. 2C is a schematic diagram looking at FIG. 2A from a direction of X.

In this electron-emitting device, a gate electrode 8A is formed on a substrate 1 through a first insulating layer 7A and a second insulating layer 7B. In addition, a cathode electrode 2 is formed on the substrate 1, and an electron emission structure (conductive film) 3 connected to the cathode electrode 2 extends toward a direction away from the substrate 1 along a side wall of the first insulating layer 7A. In the direction of X, the second insulating layer 7B is smaller in width than the first insulating layer 7A, and a recess 45 is formed between the first insulating layer 7A and the gate electrode 8A. Moreover, as is clear from FIG. 2B, the above-mentioned electron emission structure 3 projects in the direction of Z more than an upper surface of the first insulating layer 7A. That is, the electron emission structure 3 is provided with a protruded portion protruding in a direction near to the gate electrode 8A from the upper surface of the first insulating layer 7A. In addition, a part of the electron emission structure 3 comes in the recess 45. As a result, it can be said that the electron emission structure 3 is provided with the protruded portion that is formed on a surface of the insulating layer 7A located in the recess 45. Electrons are mainly emitted from this protruded portion.

In addition, FIG. 2B shows an example in which a part of the gate electrode 8A is covered with a conductive film 8B of the same material as the electron emission structure 3. This conductive film 8B can also be omitted, but in order to form a stable electric field, it is preferable to provide the conductive film 8B. As a result, in the example shown in FIG. 2B, the gate electrode is composed of the members denoted by 8A and 8B.

The electron emission structure 3 is covered with a lanthanum boride film (preferably, a lanthanum hexaboride film) 5. This lanthanum boride film 5 is deposited by the above-mentioned sputtering method. In the example of FIG. 2B, the entire electron emission structure 3 is covered with the lanthanum boride film 5, but at least the surface of the protruded portion of the electron emission structure 3 should just be covered with the lanthanum boride film 5.

It is preferable that the lanthanum boride film 5 be a poly-crystalline film of lanthanum boride rather than a single-crystalline film thereof. As compared with the single-crystalline film, the poly-crystalline film can be more easily deposited and is more stable because it can cover the electron emission structure 3 along its surface of a complicated shape with fine irregularities and can also make the internal stress thereof lower. Here, note that the single-crystalline film is lower in work function than the poly-crystalline film, but it is also possible even for the poly-crystal line film to obtain a work function lower than 3.0 eV, which is near to that of the single-crystalline film, by controlling the film thickness and the crystallite size of the film.

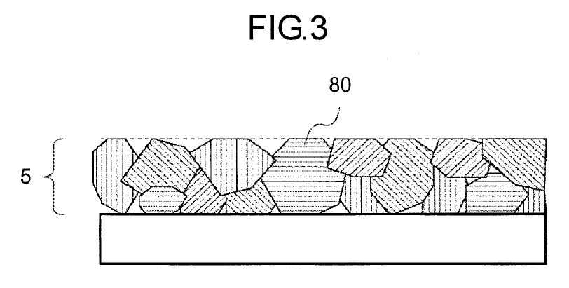

The polycrystalline film of lanthanum boride is provided with conductivity. The polycrystalline film 5 of lanthanum boride in this embodiment exhibits metallic conduction. As shown in FIG. 3, the polycrystalline film 5 of lanthanum boride according to this embodiment has a special feature as a so-called polycrystalline substance composed of a large number of crystallites 80. Each of the crystallites 80 is composed of lanthanum boride. A crystallite means the greatest assembly that can be regarded as a single crystal. Here, note that the poly-crystalline film 5 indicates a film in which the crystallites 80 are joined (placed in abutment) with one another or a plurality of lumps (aggregates) of crystallites are joined (placed in abutment) with one another to exhibit metallic conductivity, and it differs from a so-called fine particle film that is made of an aggregate of fine particles.

The poly-crystalline film 5 may be constructed such that the crystallites 80 are joined with one another or a plurality of lumps (aggregates) of crystallites are joined with one another, with voids (gaps or spaces) existing among the crystallites 80 or among the plurality of lumps (aggregates) of crystallites.

The crystallites 80 forming the polycrystalline film 5 of lanthanum boride in this embodiment each have a size equal to or larger than 2.5 nm, and the polycrystalline film 5 has a film thickness of 100 nm or less. Therefore, an upper limit of the size of the crystallites 80 forming the polycrystalline film 5 is necessarily set to 100 nm. With a poly-crystalline film having a crystallite size of equal to or larger than 2.5 nm, an emission current is stabilized (i.e., decreased in fluctuation) as compared with a poly-crystalline film having a crystallite size of less than 2.5 nm. In addition, if the crystallite size exceeds 100 nm, the film thickness of the poly-crystalline film will exceed 100 nm, as a result of which film peeling will occur to a remarkable extent, and hence, if such a film is used for an electron-emitting device, the element will have an unstable characteristic. If the film thickness of the poly-crystalline film is smaller than 2.5 nm, a work function will become larger than 3.0 eV. This is considered to be due to the fact that the composition ratio of La and B deviates greatly from 6.0, resulting in an unstable state where the poly-crystalline film becomes impossible to maintain its crystallinity. In addition, in particular, it is preferable that the film thickness be equal to or less than 20 nm, because the variation of the electron emission characteristic under such a condition is small.

The crystallite size can be typically calculated from X-ray diffraction measurements. Specifically, it can be calculated from the profile of a diffraction line by means of a method called a Scherrer method. The X-ray diffraction measurements can be used not only for the calculation of the crystallite size, but also for the investigation of the structure of the poly-crystalline film 5 composed of poly-crystals of lanthanum hexaboride, and the orientation thereof. Lanthanum hexaboride (LaB₆) has a structure that is represented by the ratio of La and B denoted by 1:6 as the stoichiometric composition thereof, and indicates those which have a simple cubic lattice (however, with respect to the composition ratio, non-stoichiometric compositions can also be included, and those which have lattice constants changed are included, too). In addition, when an observation by means of a cross-sectional TEM (transmission electron microscope) is carried out, a plurality of checked patterns which are seen substantially in parallel with one another are observed or recognized in regions corresponding to the crystallites. Consequently, two checked patterns most away from each other are selected from these plurality of checked patterns, the length of the longest line segment among line segments each connecting between an end of one checked pattern and an end of the other checked pattern can be recognized as a crystallite size (a crystallite diameter). If a plurality of crystallites are recognized in a region observed by the cross-sectional TEM, an average value of the crystallite sizes of those crystallites can be made as the crystallite size of the poly-crystalline film of lanthanum boride.

In addition, for the measurement of a work function, there are photoelectron spectroscopy such as vacuum UPS, a Kelvin method, a method of deriving a work function from a relation between an electric field and a current by measuring a field emission current in vacuum, etc., and it is also possible to calculate a work function by using them in combination.

A film (metal film) of a thickness of bout 20 nm, made of a material such as for example Mo of which the work function is known, is formed on a surface of a sharp protruded portion of a conductive needle (made of tungsten), and the electron emission characteristic of the film is measured by applying an electric field to the film in a vacuum. Then, a field enhancing factor due to the shape of the protruded portion in the form of a tip of the needle is calculated beforehand from the electron emission characteristic, and thereafter, the poly-crystalline film 5 of lanthanum boride is formed, so that the work function thereof can be obtained by calculation.

The fluctuation of an emission current emitted from the electron-emitting device indicates the magnitude of the temporal change of the emission current. It is, for example, the change of a current emitted by periodic application of a pulsed voltage of a rectangular waveform, and can be calculated by representing the magnitude of the change per unit time with a deviation, and then dividing the deviation by the average value.

Specifically, a pulsed voltage of a rectangular waveform having a pulse width of 1 ms and a frequency of 60 Hz is applied. Then, the sequence of measuring an average value of the emission current according to a voltage of a rectangular waveform having 32 consecutive pulses is carried out at an interval of 2 seconds, whereby a deviation and an average value thereof per 30 minutes are calculated. Here, note that in comparing the magnitudes of fluctuations among the plurality of electron-emitting devices, the peak values of the applied voltages are set so that the above-mentioned average values of the currents generally become equal to one another.

As materials for the cathode electrode 2 and the gate electrode 8A, there can be used metals such as for example Be, Mg, Ti, Zr, Hf, V, Nb, Ta, Mo, W, Al, Cu, Ni, Cr, Au, Pt, and Pd, or alloys of these metals. In addition, carbides such as TiC, ZrC, HfC, TaC, SiC, WC, etc., borides such as HfB₂, ZrB₂, LaB₆, CeB₆, YB₄, GdB₄, etc., nitrides such as TiN, ZrN, HfN, etc., semiconductors such as Si, Ge, etc., and so on can be used.

As materials for the electron emission structure 3, any metal can be used, but in particular, metals of high melting points are preferable. As the high melting point metals, molybdenum and tungsten can be preferably used.

As stated above, the electron-emitting device to which the manufacturing method of this embodiment can applied is an electron-emitting device that applies a voltage between a first electrode (cathode electrode) and a second electrode (gate electrode) which is arranged away from the first electrode, so that electrons are emitted from a first electrode side under the effect of an electric field. Here, note that in cases where electrons are irradiated from the electron-emitting device to an electrode other than the gate electrode, an anode electrode is arranged apart from the substrate 1, and an electric potential sufficiently higher than an electric potential applied to the gate electrode 8A is applied to the anode electrode. By doing in this manner, electrons pulled out by the gate electrode 8A (electrons emitted under the action of an electric field) are irradiated to the anode electrode. Such an electron emission apparatus becomes a three-terminal (cathode electrode, gate electrode, anode electrode) structure. The distance between the anode electrode and the substrate 1 is set to be sufficiently larger than the distance between the cathode electrode 2 and the gate electrode 8A, and is typically set to a value ranging from 500 μm to 2 mm. In the case of using this electron-emitting device as an electron source of an image display device (electron beam display), the anode electrode is formed on a luminous body such as a fluorescent body. By irradiating the luminous body with the electrons emitted from the electron-emitting device, luminescence is obtained and an image is formed.

### EXAMPLES

Hereinafter, more specific examples will be described.

### First Example

A lanthanum hexaboride target 505 of a circular shape having a diameter of 8 inches and a Si-wafer substrate 502 were used, and the substrate 502 and the target 505 were arranged in opposition to each other, as shown in FIG. 5A. The degree of vacuum at the time of exhausting at a high vacuum was set to 2×10⁻⁴ Pa, and an erosion region 504 was formed at a position spaced a distance of 60 mm from the center of the target. The value, which is obtained by dividing the discharge power of an RF power supply by the area of the target, was set to 3.1 W/cm². In addition, an argon (Ar) gas was used as a sputtering gas, and the pressure of the argon gas was set to 1.5 Pa (the mean free path λ, of Ar molecules was 4.6 mm). The distance L between the substrate 502 and the target 505 was set to 180 mm. That is, the ratio of L/λ was 39. In addition, a lanthanum boride film was deposited on the substrate 502 while moving the substrate 502 in an arrow direction of FIG. 5A.

### Comparative First Example

A lanthanum boride film of a first comparative example was formed under the same conditions as those of the above-mentioned first example excepting that the distance L between the substrate and the target was set to 90 mm. At this time, the ratio of L/λ was 19.5.

The lanthanum boride films obtained according to the first example and the first comparative example were individually analyzed by means of an X-ray diffraction method. For the film of the first example, the FWHM of a (100) peak was 0.50 degrees, and a value obtained by dividing the integral value of the (100) peak by the integral value of a (110) peak was 5.7. On the other hand, for the film of the first comparative example, the FWHM of a (100) peak exceeded 0.60 degrees, and a value obtained by dividing the integral value of the (100) peak by the integral value of a (110) peak was 2.8. That is, the first example was able to obtain the film of higher crystallinity oriented to a (100) surface than that of the first comparative example. In addition, in the first example, the in-surface variation of the FWHM of the (100) peak became smaller than 5%, and was able to form a homogeneous lanthanum boride film over the entire substrate.

### Second Example

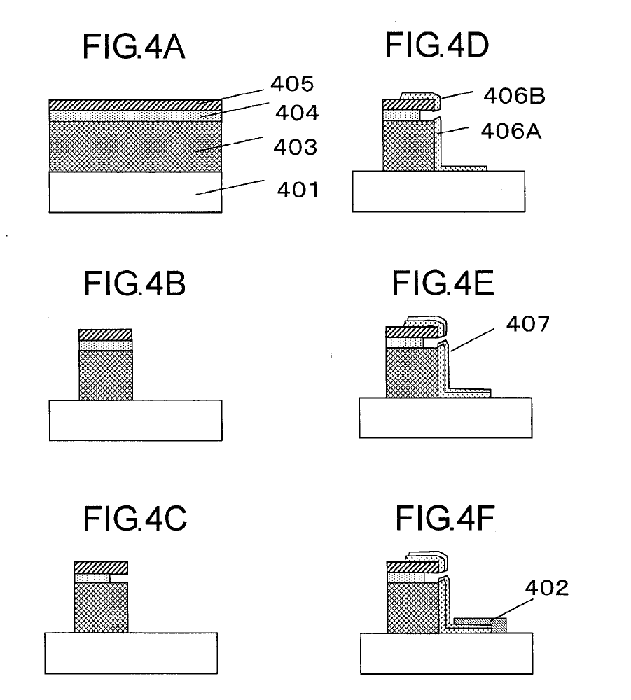

A manufacturing method of an electron-emitting device according to a second example will be described with reference to FIG. 4A-FIG. 4F. FIG. 4A-FIG. 4F are diagrammatic illustrations sequentially showing the manufacturing steps of the electron-emitting device.

A substrate 401 is a substrate for supporting an element in a mechanical manner. In this example, a PD 200, which is a low sodium glass developed for plasma displays, was used as the substrate 401.

First, as shown in FIG. 4A, insulating layers 403, 404 and a conductive layer 405 were laminated on the substrate 401. The insulating layers 403, 404 are insulating films, respectively, which are made of materials which are excellent in processability. In the second example, the insulating layer 403 of silicon nitride (SiₓN_{y}) having of a film thickness 500 nm and the insulating layer 404 of silicon oxide (SiO₂) having a film thickness of 30 nm were formed by means of a sputtering method. In addition, the conductive layer 405 of tantalum nitride (TaN) having a thickness of 30 nm was formed also by the sputtering method.

Then, a resist pattern was formed on the conductive layer 405 by means of a photolithography technology, after which the conductive layer 405, the insulating layer 404 and the insulating layer 403 were processed in this order by the use of a dry etching technique (see FIG. 4B). A CF₄ type gas was used as a process gas at this time. As a result of having performed RIE (Reactive Ion Etching) using this gas, the angle of a side surface (inclined surface) of the insulating layer 403 was about 80 degrees with respect to a horizontal surface of the substrate.

After exfoliating the resist, using a mixed solution of ammonium fluoride and fluoric acid, which is called buffered fluoric acid (BHF), the insulating layer 404 was etched to form a concave portion (recess portion) (see FIG. 4C).

As shown in FIG. 4D, molybdenum (Mo) was made to adhere on the side surface and an upper surface (an inner surface of the concave portion) of the insulating layer 403, whereby an electron emission structure (conductive film) 406A was formed. Here, note that at this time, a molybdenum layer 406B was adhered also on the conductive layer 405 (gate electrode). In this example, an EB vapor deposition method was used as a deposition method.

Subsequently, as shown in FIG. 4E, a lanthanum hexaboride film 407 was formed on the electron emission structure 406A. The lanthanum hexaboride film 407 was formed by means of the same method as the first example. That is, at the time of sputtering the lanthanum hexaboride film, the value, which is obtained by dividing the discharge power of an RF power supply by the area of a target, was set to 3.1 W/cm², and the pressure P of an Ar gas was set to 1.5 Pa, and the distance L between the substrate and the target was set to 180 mm, i.e., L/λ was set to 39. Then, the substrate with the structure as shown in FIG. 4D being formed thereon and the lanthanum hexaboride target were arranged in opposition to each other, and the lanthanum hexaboride film 407 was formed by means of a moving deposition method.

Thereafter, as shown in FIG. 4F, a cathode electrode 402 was formed by means of the sputtering method. Copper (Cu) was used for the cathode electrode 402. The cathode electrode has a thickness of 500 nm.

The electron-emitting device thus formed was put in a vacuum device, and the interior of the vacuum device was exhausted up to 10⁻⁸ Pa. Then, a pulsed voltage of a rectangular waveform having a pulse width of 1 ms and a frequency of 60 Hz was repeatedly applied between the cathode electrode 402 and the gate electrode 405 in such a manner that the electric potential of the gate electrode 405 became higher than that of the cathode electrode. A gate current flowing into the gate electrode 405 was monitored, and at the same time, an anode electrode was arranged at a position spaced upwardly by a distance of 5 mm from the substrate 401, and a current (anode current) flowing into the anode electrode was also monitored, so that the variation of an anode emission current was calculated. Thus, the variation (fluctuation) of the emission current (anode current) was obtained by performing the sequence of measuring an average value of the emission current according to a voltage of a rectangular waveform having 32 consecutive pulses at an interval of 2 seconds, and calculating a deviation and an average value thereof per 30 minutes. Then, a value {(standard deviation/average value)×100(%)} of the data thus obtained was calculated.

In addition, for the purpose of a comparison, an electron-emitting device was also prepared for trial which has a lanthanum hexaboride film formed by means of the same method as the first comparative example, and the same measurements as stated above were performed.

As a result, the electron-emitting device of this example had an average of the current variation value which is 0.8 times in comparison with the electron-emitting device of the comparative example, and was able to continue good electron emission with little change of brightness over a long period of time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-018202, filed on Jan. 29, 2009, which is hereby incorporated by reference herein in its entirety.

What is claimed is:

1. A manufacturing method of an electron-emitting device provided with a lanthanum boride film as an electron-emitting member, the method comprising the steps of:
preparing a substrate and a target of lanthanum boride; and
depositing a lanthanum boride film on the substrate by means of a sputtering method while moving the substrate and the target relative to each other in a state where the substrate and the target are arranged in opposition to each other;
wherein
when a mean free path of sputtering gas molecules at the time of deposition is λ (mm) and a distance between the substrate and the target is L (mm), a ratio of L/λ is set to a value equal to or larger than 20; and
a value which is obtained by dividing a discharge power value by an area of the target is set to be in a range of from 1 W/cm² or more to 5 W/cm² or less.

2. A manufacturing method of an electron emission device according to claim 1, wherein
the sputtering gas is an argon gas.

3. A manufacturing method of a lanthanum boride film, comprising the steps of:
preparing a substrate and a target of lanthanum boride; and
depositing a lanthanum boride film on the substrate by means of a sputtering method in a state where the substrate and the target are arranged in opposition to each other,
wherein
when a mean free path of sputtering gas molecules at the time of deposition is λ (mm) and a distance between the substrate and the target is L (mm), a ratio of L/λ is set to a value equal to or larger than 20.
